(19) United States
(12) Patent Application Publication
(10) Pub. No.: US 2022/0182498 A1
(43) Pub. Date: Jun. 9, 2022

(54) SYSTEM MAKING DECISION BASED ON DATA COMMUNICATION

(71) Applicant: HITACHI, LTD., Tokyo (JP)

(72) Inventors: Rathour Swarn SINGH, Tokyo (JP); Tsunamichi TSUKIDATE, Tokyo (JP); Tasuku ISHIGOOKA, Tokyo (JP)

(73) Assignee: HITACHI, LTD., Tokyo (JP)

(21) Appl. No.: 17/437,346

(22) PCT Filed: Dec. 20, 2019
(86) PCT No.: PCT/JP2019/050011

§ 371 Date: Sep. 8, 2021

(30) Foreign Application Priority Data
Mar. 19, 2019 (JP) 2019-051272

(51) Int. Cl. H04N 1/00; G06V 20/58; H03M 7/30

(52) U.S. Cl. CPC H04N 1/00095; B60W 60/001; H03M 7/60; G06V 20/58

(57) ABSTRACT

A data communication acquires a map image, determines high- and low-risk areas in the map, determines whether to transmit data related to the high- or low-risk areas, detects objects around the system, determines a position in the map image for each of the objects detected, determines whether the objects belongs to the high- or low-risk areas, determines a data compression ratio for each of the objects detected, compresses data related to each of the objects, compresses data related to each of the objects belonging to the high-risk area when data related to the high-risk area is determined to be transmitted, compresses data related to each of the objects belonging to the low-risk area when data related to the low-risk area is determined to be transmitted, receives reply data replied in association with the compression data transmitted, and makes a decision in accordance with the reply data.

### TECHNICAL FIELD

The present invention relates to a system making a decision based on data communication.

### BACKGROUND ART

Increase in level of automation increases demand for computational capability on an edge side. Computational and decision-making capabilities of autonomous systems face the challenge of dealing with unknown obstacle situations. It is desirable to assist and support secure and optimal decision making of the autonomous systems and reduce a burden on the computational capability.

PTL 1 describes an example of a system that makes a decision based on data communication. The system identifies an area on a map, corresponding to a portion within a distance threshold value.

The system compresses images in different areas with different data compression ratios.

Unfortunately, the system requires a high computational capability due to use of feature matching between a map and an image, which conflicts with real-time performance requirements.

The system also transmits a compressed image to a remote system. This can be achieved when traffic is not congested or when an effective communication rate is high. However, when traffic is congested, an excessive load is applied on a communication network to limit the amount of data that can be transmitted, and thus the system may not operate efficiently.

One of limitations of PTL 1 is that there is no description of a method for reducing data to reduce the network load.

Second, PTL 1 does not describe a decision-making technique. For example, there is no description of how the system determines which data are to be transmitted based on a vehicle state, a driving scenario, a vehicle purpose, a network availability, and so on.

Finally, PTL 1 describes a difficult scenario in which a vehicle can benefit from decision-making capability of a human operator or a computing system with higher performance.

To allow a system, which is fully autonomous, partially autonomous, or semi-autonomous, to operate safely, continuous communication or connection with a remote system, such as a supervisory system, is required.

### CITATION LIST

### Patent Literature

PTL 1: US 2016/0283804 A

### SUMMARY OF INVENTION

### Technical Problem

In particular, conventional techniques each have a problem that the amount of data to be communicated is large.

The present invention is made to solve such a problem, and an object of the present invention is to provide a system making a decision based on data communication and being capable of reducing the amount of data to be communicated.

### Solution to Problem

A system according to the present invention makes a decision based on data communication, and includes a function of acquiring a map image, a function of determining a first area and a second area in the map image, a first transmission determination function of determining whether to transmit data related to the first area through a communication network, a second transmission determination function of determining whether to transmit data related to the second area through the communication network, a function of detecting objects around the system, a function of determining a position in the map image for each of the objects detected, a function of determining whether each of the objects detected belongs to the first area, based on the position of the corresponding one of the objects in the map image, a function of determining whether each of the objects detected belongs to the second area, based on the position of the corresponding one of the objects in the map image, a compression ratio determination function of determining a data compression ratio for each of the objects detected, based on a distance to the corresponding one of the objects, a function of compressing data related to each of the objects detected in accordance with the data compression ratio of the corresponding one of the objects to generate compression data related to the corresponding one of the objects, a function of transmitting the compression data related to each of the objects belonging to the first area through the communication network when data related to the first area is determined to be transmitted, a function of transmitting the compression data related to each of the objects belonging to the second area through the communication network when data related to the second area is determined to be transmitted, a function of receiving reply data replied in association with the compression data transmitted, through the communication network, and a function of making a decision in accordance with the reply data.

The system according to the present invention makes a decision based on data communication, and includes a processor that is capable of: acquiring a map image; determining a first area and a second area in the map image; determining whether to transmit data related to the first area through a communication network as a first transmission determination; determining whether to transmit data related to the second area through the communication network as a second transmission determination; detecting objects around the system, a function of determining a position in the map image for each of the objects detected; determining whether each of the objects detected belongs to the first area, based on the position of the corresponding one of the objects in the map image, a function of determining whether each of the objects detected belongs to the second area, based on the position of the corresponding one of the objects in the map image; determining a data compression ratio for each of the objects detected, based on a distance to the corresponding one of the objects; compressing data related to each of the objects detected in accordance with the data compression ratio of the corresponding one of the objects to generate compression data related to the corresponding one of the objects; transmitting the compression data related to each of the objects belonging to the first area through the communication network when data related to the first area is determined to be transmitted; transmitting the compression data related to each of the objects belonging to the second area through the communication network when data related to the second area is determined to be transmitted; receiving reply data replied in association with the compression data transmitted, through the communication network; and making a decision in accordance with the reply data.

The present specification includes the disclosure of Japanese Patent Application No. 2019-051272, which is the basis of the priority of the present application.

### Advantageous Effects of Invention

The system according to the present invention appropriately determines not only whether to transmit data on objects but also a data compression ratio of each of the objects, so that the amount of data to be communicated can be reduced.

Specific examples of the present invention can individually obtain effects below as examples.

An onboard computing platform (edge side computing platform) can sample, filter, and compress sensor data before transmitting it to a remote system. The edge-side computing platform can also receive an operation instruction from a remote system for secure and optimal decision making. The remote system may be, for example, a remote assistance system, which may involve a trained human operator, or may be a computing platform with high computational capability. The remote assistance system can provide a secure and optimal operation instruction to the edge side system requesting assistance.

The edge side system can receive the secure and optimal operation instruction from the remote system in real time without delay. This is especially effective in the following situations where,

a vehicle itself cannot make a secure and optimal decision,

the vehicle wants to pass control to a secure driver, but the secure driver is unaware,

the vehicle has encountered an unknown or unexplained failure situation,

the vehicle has a failure in a function, an operation, or a system,

sensor data in the vehicle needs to be uploaded for learning to improve the decision-making capability of a remote system, and

an occupant or passenger in the vehicle requests assistance.

In any of the above situations, the remote system may require enormous information on vehicle conditions and driving scenarios to make secure and optimal decisions. Thus, a principle is to use a map of the surrounding environment and update static and dynamic information on the map to make secure and optimal decisions. In an embodiment of the present invention, the edge-side system classifies the vehicle environment into a high-risk area (a travelable area) and a low-risk area (a static map area, a portion including a landmark on the map, a building that is not a part of a road network/graph, etc.) based on the map and the positional information on the vehicle. Then, the edge-side system can determine whether to update or transmit a dynamic traffic participant in the vehicle environment to the remote assistance system based on accuracy of a position of the vehicle, accuracy of conditions (vehicle position, speed, throttle, braking, steering) of the vehicle, and the map. Next, the edge-side system performs a clustering operation based on information on a detected object in the filtered vehicle environment, and then identifies a convex hull surrounding each cluster. Then, the edge-side system performs a cropping process of the detected object cluster in each area from data on the vehicle environment. The edge-side system finally selects an adaptive compression ratio for the object cluster detected and cropped based on an effective communication rate of a network, a distance from an environmental recognition sensor module to the object cluster detected, and a driving scenario.

### BRIEF DESCRIPTION OF DRAWINGS

FIG. 1 is a diagram illustrating an example of a camera image captured by a front camera mounted on a vehicle. This vehicle is equipped with a system according to an embodiment of the present invention.

FIG. 2 is a diagram illustrating an example of various sensors mounted on a vehicle.

FIG. 3 is a flowchart illustrating an algorithm according to an embodiment of the present invention.

FIG. 4 is a block diagram illustrating a data flow according to an embodiment of the present invention.

FIG. 5 is a block diagram illustrating a configuration of a decision-making unit according to an embodiment of the present invention.

FIG. 6 is a block diagram illustrating a configuration of a compression unit according to an embodiment of the present invention.

FIG. 7 is a diagram illustrating an example of a map of environment. The map of the environment represents a static feature and an appearance of the environment at the time when the map is prepared. Generally, the map represents the environment captured by the front camera (FIG. 1 except a dynamic obstacle).

FIG. 8 is a diagram illustrating a cropped portion of the map of FIG. 7. FIG. 8 represents a high-risk area, and a portion remaining in FIG. 7 after the high-risk area (FIG. 8) is cropped represents a low-risk area.

FIG. 9 is a diagram illustrating corrected camera sensor data captured by a front camera mounted on a vehicle when a decision-making unit performs clustering on detected objects and passes both of a high-risk area and a low-risk area to a convex hull estimation unit.

FIG. 10 is a diagram illustrating corrected camera sensor data captured by the front camera mounted on the vehicle when the decision-making unit performs clustering on detected objects and passes only the high-risk area to the convex hull estimation unit.

FIG. 11 is a diagram illustrating a detected and cropped object cluster from a camera image belonging to a low-risk area.

FIG. 12 is a diagram illustrating a detected and cropped object cluster from a camera image belonging to a high-risk area.

FIG. 13 is a diagram illustrating a vehicle environment reproduced in a remote assistance system, using a map of an environment and a detected and cropped object cluster received from a vehicle.

FIG. 14 is a diagram illustrating an example of a configuration of a system for making a decision based on data communication, according to a second embodiment.

FIG. 15 is a diagram illustrating an example of a high-risk area and a low-risk area.

### DESCRIPTION OF EMBODIMENTS

Hereinafter, embodiments of the present invention will be described with reference to the accompanying drawings. The present invention can be implemented as a system for making a decision based on data communication. Systems, functions, and methods, described herein are exemplary and do not limit the scope of the invention. Each aspect of the systems and methods disclosed herein can be configured in a variety of different combinations of configurations, all of which are assumed herein.

In each embodiment, a particular component or description can be replaced with a component or description in another embodiment. For example, those skilled in the art can achieve details of a certain process in a first embodiment according to a specific example described in a second embodiment.

### First Embodiment

A configuration according to the first embodiment provides a method for improving or assisting completely autonomous or semi-autonomous operation of a vehicle by receiving an operation instruction or assistance from a remote assistance system. The remote assistance system may include a human operator or a computing platform with high computational capability. The vehicle may provide sensor data to the remote assistance system to receive an operation instruction or assistance from the remote assistance system. The sensor data includes an image or a video stream of vehicle environment, light detection and ranging, or laser imaging detection and ranging (LIDAR) data, radio detection and ranging (RADAR) data, and the like. In contrast, the remote assistance system may assist the vehicle in detecting, classifying, or predicting behavior of an object, and assist in making a secure and optimal decision in any driving scenario. Thus, the vehicle can benefit from secure and optimal decision-making capability of a remote human operator, or high computational capability of a remote assisted computing platform.

Examples of a rare driving scenario in which a vehicle may require decision-making capability of a remote human operator or high computational capability of a remote assisted computing platform include the following case. In the case, the vehicle requires a vehicle position determining unit to execute a function requiring high computational capability that does not converge within a required limit and cannot be executed using an onboard computing platform. In such a situation, the vehicle may require assistance from a remote assistance system with high computational capability to perform the function. This causes the vehicle to upload sensor data to the remote assistance system with high computational capability, thereby receiving highly accurate positional information.

In another example, an onboard decision-making unit of a vehicle may require an onboard secure driver to take over control of the vehicle. However, the secure driver is unaware of this or is not careful about this, and thus may not receive control within a predetermined time frame, which can lead to an accident. In such a scenario, the vehicle can require remote assistance to take over vehicle control because the secure driver is not careful.

In another example, onboard detection of a vehicle or a decision-making and planning unit encounters an unknown situation or an unknown obstacle, and is not confident enough for the vehicle to make a secure operation decision. In such a case, the vehicle may request remote assistance. Similarly, when the onboard detection and a recognition system fail to detect a potential obstacle in real time, or when the vehicle encounters an unknown obstacle, this situation may lead to a traffic accident, and then a user and a passerby may be injured. Thus, the vehicle can upload sensor data on the situation to the remote assistance system and receive a secure and optimal operation instruction for the sensor data.

In yet another example, the vehicle may need to upload its sensor data to a cloud for online learning. This is to improve decision-making capability, detection, etc. In such a scenario, a bandwidth restriction or another data communication restriction may prohibit real-time uploading of sensor data. Such a scenario may cause compression of sensor data to degrade performance. Thus, in such a scenario, applying an embodiment of the present invention enables vehicle sensor data to be uploaded in real time without losing detailed information.

When the remote assistance system assists the vehicle, the remote assistance system may request various data representing an environment around the vehicle in real time to make a secure and optimal decision. For example, when a remote human operator takes over control of the vehicle remotely, video or image data representation of the surroundings of the vehicle is required to make a secure decision. However, a platform with high computational capability may require sensor data to make a secure and optimal decision.

In view of the above example, there are provided a method and a function for sampling, filtering, and compressing sensor data representing the vehicle environment before it is transmitted and uploaded to the remote assistance system. In one example, the vehicle receives an image of the environment from a camera mounted on the vehicle. The vehicle may receive a map of the environment (lane information, a stop line, etc.) such as a vector map. The map may include strength of an environment during navigation and an image file. The map may also include various road structural features and locations. The vehicle may receive a global position and its state (global speed, direction, acceleration, etc.). The vehicle may also identify itself or determine its position on the map based on its condition and position. The vehicle may divide the map into high-risk and low-risk areas based on a position of the vehicle on the map. In one example, the high-risk area may include an area related to driving conditions of the vehicle (a road on which the vehicle is traveling and the vicinity of the road). Then, the vehicle may determine importance and priority of updating the remote assistance system with high-risk area information, low-risk area information, or both, based on a position of the vehicle and accuracy of conditions thereof. For example, when a position of the vehicle is within an acceptable threshold value, the vehicle may determine to transmit only an object cluster detected and cropped in the high-risk area. One of reasons behind such decision-making is that the low-risk area contains a structural or landmark feature or a static feature that is useful for determining a position of the vehicle. In contrast, the high-risk area is important in decision-making in driving. The vehicle may also identify an object in an environment with the help of an object detection sensor and its function. After the object is identified, the vehicle may perform a clustering function for clustering the detected object based on a Euclidean distance, a class, or an object feature. After clustering the detected object, the vehicle may determine a boundary box or convex hull that surrounds each cluster. Then, the vehicle may crop each of object clusters detected in the high-risk and low-risk areas from the sensor data. Finally, the vehicle may determine a different compression ratio for each cluster based on a driving scenario and a bandwidth restriction of the vehicle. When a bandwidth availability is very low, the vehicle may transmit only boundary box or convex hull information for each detected object cluster.

In some cases, the functions described herein may be based on sensor data other than camera sensor data. For example, the sensor data may come from various sensors such as a LIDAR sensor, a RADAR sensor, an ultrasonic sensor, and an audio sensor. When a computing platform mounted on the vehicle allows fusion of multiple sensors, fusion sensor data may be used. In the case of object detection and a convex hull estimation unit, any available configuration can be used. In one example, the LIDAR sensor provides point cloud data for the environment, and the point cloud data represents an object in the environment. LIDAR information can be used for clustering and convex hull estimation. After that, a detected object cluster may be cropped from LIDAR data, and then the decision-making unit may determine the importance and priority of the detected and cropped object cluster. After the importance is determined, a bandwidth-based compression unit may determine the compression ratio of each of detected and cropped object cluster before the importance is transmitted to the remote assistance system. A similar method can be used for RADAR sensor data, and the same applies to multiple sensor fusion data.

Hereinafter, an example of the system according to the first embodiment will be described in detail. An example of a system for making a decision based on data communication will be described using an automobile. However, the present invention can also be implemented in other systems, and can also be applied to, for example, vehicles (passenger cars, buses, trucks, trains, golf carts, etc.), industrial machines (construction machines, farm machines, etc.), robots (ground robots, water robots, warehouse robots, service robots, etc.), aircraft (fixed-wing aircraft, rotary-wing aircraft, etc.), and ships (boats, ships, etc.). The present invention can also be applied to vehicles other than these.

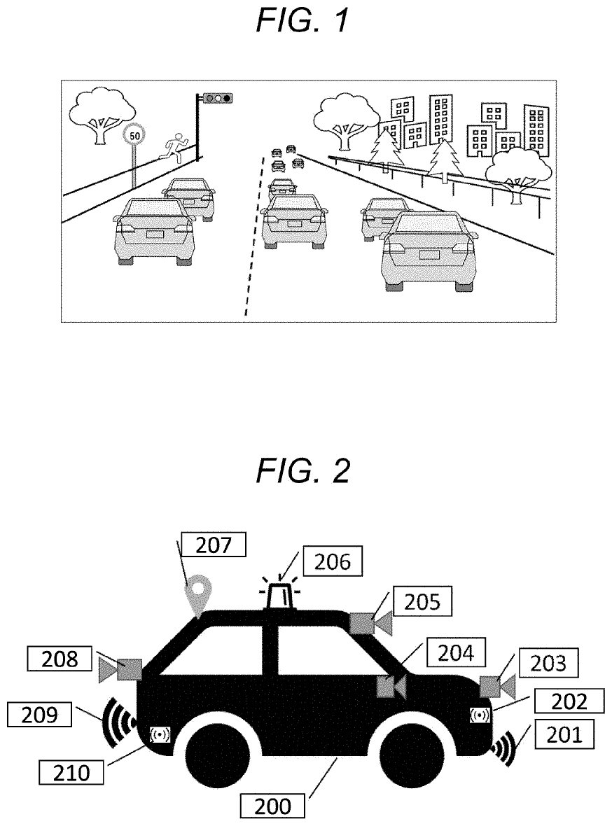

FIG. 1 shows an environment captured by a front camera of the vehicle.

FIG. 2 illustrates a vehicle 200 (passenger car). The vehicle 200 includes various sensors to assist driving or for fully autonomous driving. Examples of the sensors include a LIDAR sensor 206, a global positioning system (GPS), an inertial navigation system (INS) 207, cameras 203 to 205, and 208, RADAR sensors 209 and 201, and ultrasonic sensors 202 and 210. These are merely examples for describing the invention. The vehicle may have another sensor configuration.

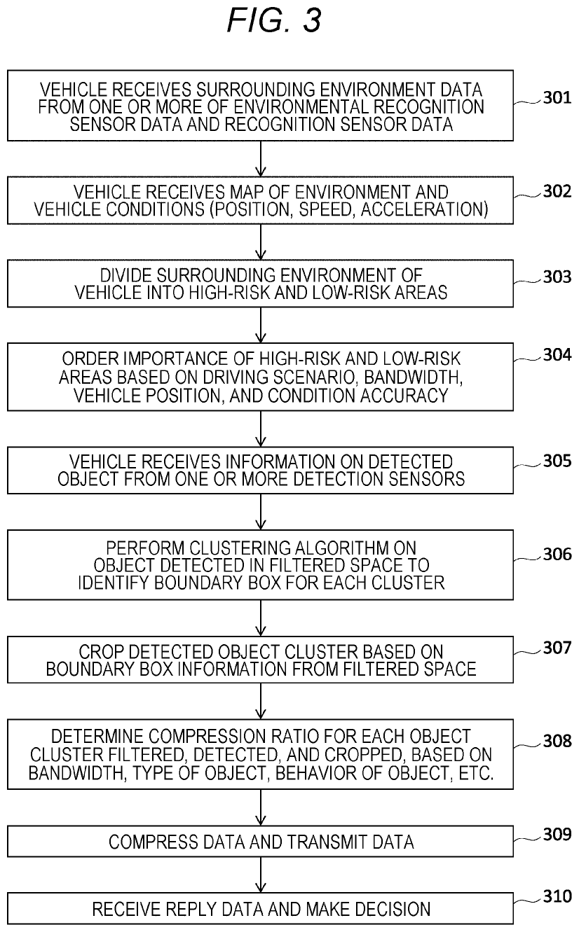

FIG. 3 illustrates a flowchart 300 of an algorithm of the present embodiment. The vehicle may receive environmental data from one or more environmental recognition sensors (step 301). The vehicle may further receive a map of an environment and conditions and a position of the vehicle (step 302). The vehicle may also divide a surrounding environment into high-risk and low-risk areas based on the position of the vehicle and the map of the environment (step 303). The vehicle may also filter sensor data in the high-risk and low-risk areas based on a bandwidth, the position of the vehicle, and accuracy of the conditions thereof (step 304). One of purposes of filtering the sensor data in the areas is to reduce the size of the data before transmission. The vehicle may also cluster detected objects into several groups in the corresponding areas with the filtered sensor data based on a Euclidean distance, a feature, a detected object class, etc., with the help of an object detection sensor and an algorithm (steps 305 and 306). The vehicle may also identify a convex hull or boundary box for each of the detected object clusters in the high-risk and low-risk areas. The vehicle may crop the detected object clusters from data of the environmental recognition sensors such as the cameras, the LIDAR sensor, the RADAR sensor, etc., or use a sensor fusion method to fuse the data of the cameras, the LIDAR sensor, and the RADAR sensor. Alternatively, object cluster information detected from the data of the environmental recognition sensors may be cropped (step 307). The vehicle may also determine a compression ratio for each of the filtered, detected, and cropped object clusters based on a bandwidth availability, an object type, an object behavior, a driving scenario, etc. (step 308). The vehicle may also provide the remote system with a filtered, detected, cropped, and compressed object cluster (step 309), and receive a secure and optimal operation instruction from the remote system (step 310).

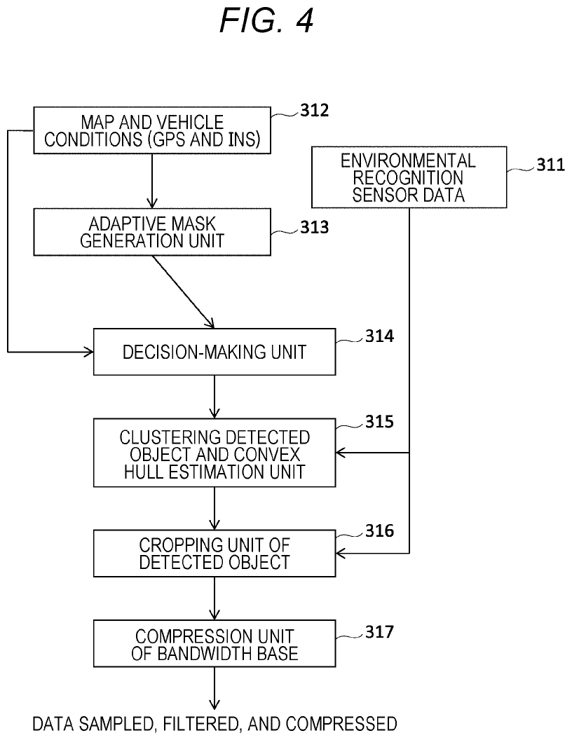

FIG. 4 is a block diagram including functional blocks showing a flow of data in the present embodiment. The flow of data is shown in each block. A block 311 is configured to provide data on a vehicle environment and information on a detected object. A block 312 is configured to provide an adaptive mask generation unit with map data and vehicle condition-location information to divide the vehicle environment into high-risk and low-risk areas. Blocks 313 and 314 represent decision-making units. One of the goals of the decision-making units is to pass a mask (the high-risk area, the low-risk area, or both) to a block 315. Thus, sensor data is filtered using the mask to reduce the size of the data for processing. The block 315 represents clustering of detected objects and convex hull estimation of the detected object clusters in the filtered areas (or output of the block 314). A block 316 is configured such that a cropping unit of the detected object clusters performs extraction of the detected object clusters only for transmission. A block 317 represents the bandwidth-based compression unit.

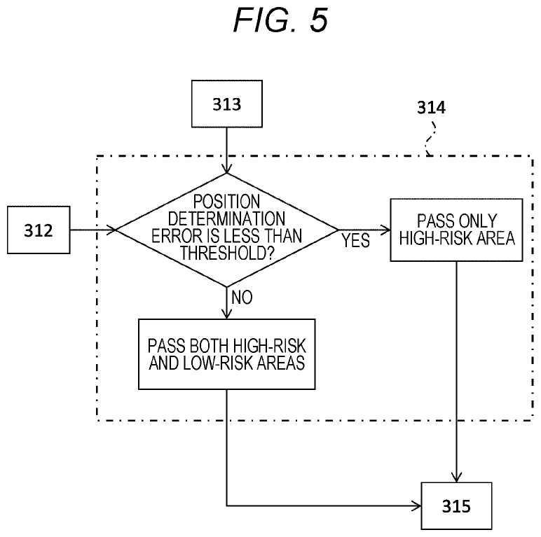

FIG. 5 illustrates the decision-making unit. The decision-making unit selects an adaptive mask (i.e., output of the block 313). Thus, when the sensor data representing the vehicle environment is filtered based on a position of the vehicle and accuracy of conditions thereof, a size of the sensor data required for clustering of the detected objects can be reduced. One of roles and purposes of the decision-making unit is to determine the priority and importance of requirements for information on the high-risk and low-risk areas for making a decision of secure and optimal operation. For example, when a variance, a deviation, and a bias matrix of the conditions of the vehicle are each within a predetermined threshold value, or when a position of the vehicle and the conditions thereof are provided with required accuracy (i.e., when the position of the vehicle can be determined with accuracy less than a centimeter) in the block 312, it is sufficient to transmit only data on the high-risk area to the remote assistance system. When the position of the vehicle and the accuracy of the conditions thereof are each lower than the threshold value, data information on both the high-risk and low-risk areas needs to be transmitted to the remote assistance system.

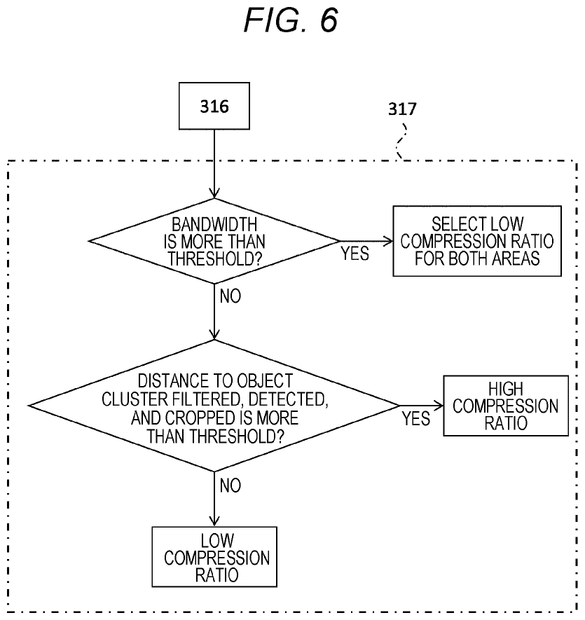

FIG. 6 illustrates an algorithm for a bandwidth-based compression unit. The object clusters detected and cropped in the filtered areas are further compressed to reduce the size of data for real-time transmission. A compression ratio for each of the object clusters filtered, detected, and cropped is calculated based on the bandwidth availability and a distance from the corresponding one of the object clusters detected, cropped, and filtered to the vehicle. Thus, when the available bandwidth is too low, only information on the convex hull and the boundary box can be transmitted to the remote system. In the above scenario, an object such as a passenger car can be represented as a 3D box that does not contain any graphic information.

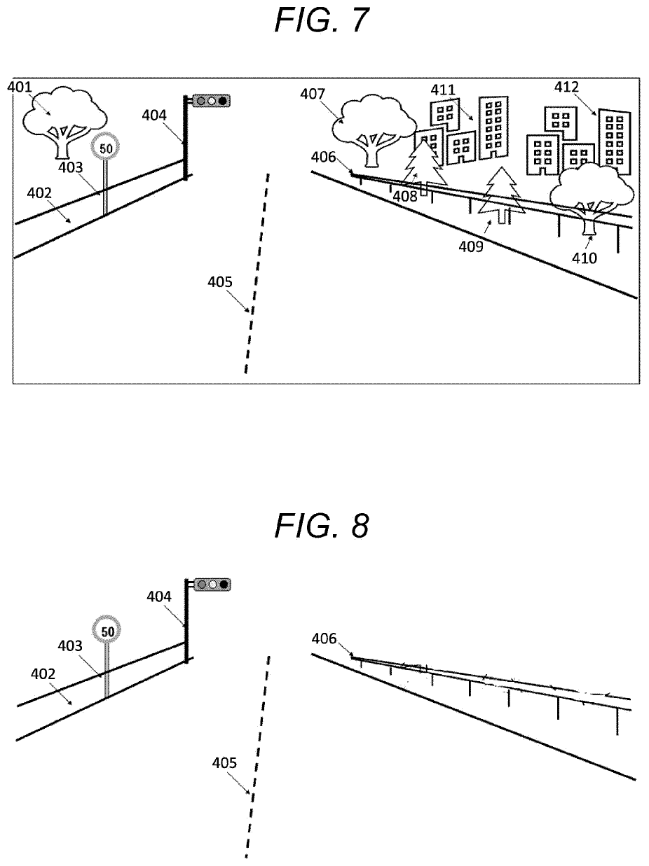

FIG. 7 illustrates a map of an environment. The map may show various features in an environment of the vehicle. For example, the view in FIG. 7 may correspond to a forward image view of the environment illustrated in FIG. 1. In another case, decision making requires a right, left, or rear view, and corresponding parts of the map may be used. The map may also show a target area related to a driving scenario for secure decision making. FIG. 7 may represent a current neighborhood of the vehicle environment based on a position of the vehicle. Thus, a portion on the map corresponding to the position of the vehicle may be clipped from map data representing the current neighborhood of the vehicle environment. The map may include road structural features 402 to 406. In some cases, the map may include a road map. The road map may be associated with a street view, point cloud data, intensity data, a road structure (a stop sign, or a traffic light), and another driving-related feature. The map may include map feature image views different in intensity and weather conditions. The map may also include a static feature or landmark features 401, and 407 to 412. Although the features are not a part of the road, the features provide information important in determining a position of the vehicle positioning when an onboard positioning function has a large deviation.

FIG. 8 illustrates a cropped portion on the map illustrated in FIG. 7. To crop the map illustrated in FIG. 7, a position and conditions of the vehicle, and map road information (travelable area information), may be used. One of purposes of the cropping is to divide the vehicle environment into high-risk and low-risk areas. Thus, it can be said that the high-risk area is important in making a decision on driving, while information on the low-risk area is important in determining a position of the vehicle. The clipped portion (FIG. 8) of the map (FIG. 7) represents the high-risk area with the static road structural features (travelable areas) 402 to 406. The high-risk area has a boundary that is slightly expanded to include the road structural feature 402 representing a sidewalk, which is important in making a decision on secure driving in an urban area. When more information about the surrounding environment is required, dividing the vehicle environment into the high-risk and low-risk areas may be defined by a remote human operator or a remote computing platform with high computational capability. Similar techniques for dividing a vehicle environment into high-risk and low-risk areas can be executed across multiple views (an omnidirectional view obtained by front, left, right, and rear camera sensors, representing a 360° view of the vehicle environment).

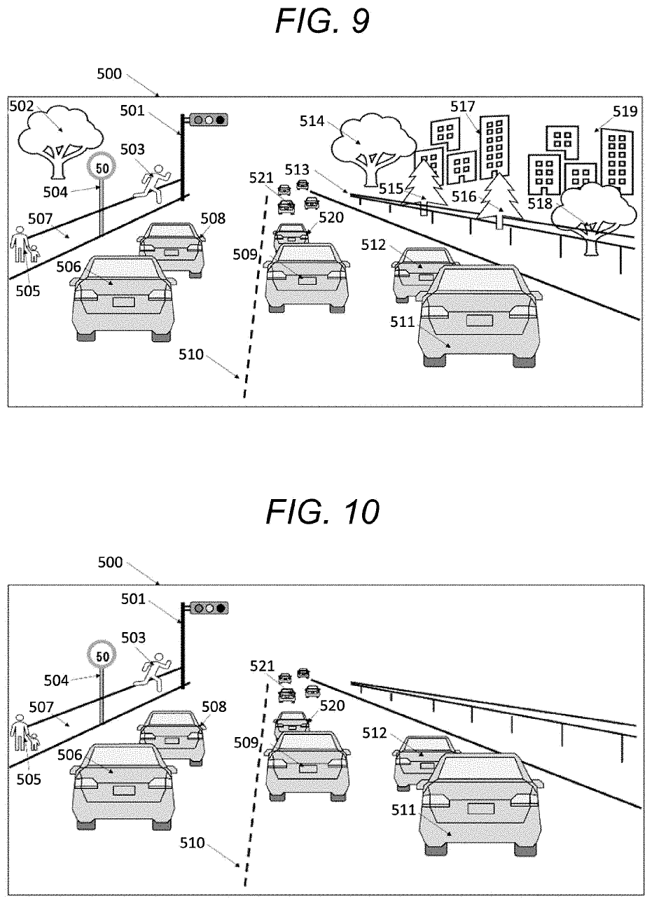

FIG. 9 illustrates a driving environment image 500. The image is captured by a front camera mounted on the vehicle, and is captured when the decision-making unit (block 314) determines that information on both the high-risk and low-risk areas is needed to make a secure decision. For example, the camera may be mounted on a front portion of the vehicle to capture the image 500 in front view of the vehicle environment. Another view is also available. For example, the vehicle may fuse a front camera, a left camera, a right camera, and a rear camera to capture an omnidirectional view of the environment based on a movement direction of the vehicle and a driving scenario. The image 500 may include various features that the vehicle may encounter in the vehicle environment, such as a road sign 504, a traffic light 501, lane information 510, a sidewalk lane 507, dynamic features such as pedestrians 505 and 503, and traffic participants 506, 508, 509, 511, 512, 520, and 521, for example, static features 502, and 514 to 519, and a guardrail 513.

FIG. 10 represents information on both the high-risk and low-risk areas used by the block 315 when a position of the vehicle and conditions thereof are each not within a required accuracy limit. In such a scenario, the low-risk area may be required to determine an absolute position, and information on the high-risk area may be available for determining secure and optimal operation. Similarly, when the position of the vehicle is sufficiently accurate, the block 315 may use FIG. 10 (representing only the information on the high-risk area) to determine secure and optimal driving operation.

Compression and transmission of the image 500 may not work well because of a bandwidth restriction. A high compression ratio leads to information loss. Maps used for driving continue to increase in amount of information. To make a secure and optimal decision, it may be sufficient to upload only dynamic information in the vehicle environment for remote assistance. Thus, the vehicle environment captured by the sensors mounted on the vehicle is sampled, filtered, compressed, and transmitted. In the case of the image 500, the traffic participants 506, 508, 509, 511, 512, 520, and 521 (FIG. 10) may be useful for making a secure and optimal driving decision, while the static features 502, and 514 to 519 may be useful for determining a position of the vehicle. Thus, in the case of the image 500, behavior of the pedestrian 503 is considered unpredictable, so that the remote assistance system may instruct the vehicle to slow down while the pedestrian 503 crosses. Additionally, the amount of traffic in the right lane is considered too large, so that the remote assistance may instruct the vehicle to change a lane. However, in some scenarios, the vehicle may ignore features like the static features 502, and 514 to 519, in the image 500, or may determine that the features are not transmitted, when a position deviation of the vehicle is within a tolerance limit. The reason is that these features are static and may not significantly affect decision-making of the vehicle. As described above, the present embodiment enables the amount of information to be reduced before the image 500 is transmitted to the remote assistance system.

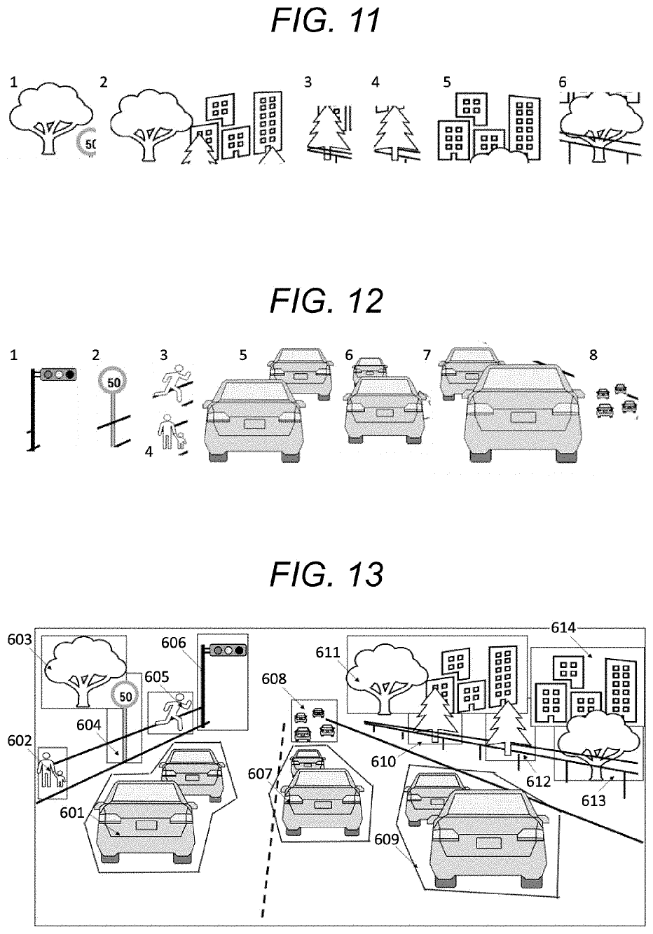

FIGS. 11 and 12 represent object clusters detected and cropped, belonging to the low-risk area (symbols 1 to 6) and the high-risk area (symbols 1 to 8), respectively. For example, each detected object can be clustered based on a detected class, a Euclidean distance, a size, etc. Any object detection sensor (e.g., a RADAR sensor, a LIDAR sensor, a camera, a stereo camera, an infrared camera, a thermal camera, an ultrasonic sensor, etc.) can be used for object detection. In the present embodiment, a plurality of sensors is applied for object detection. The present embodiment may also be used by being connected to an automated vehicle, and thus each vehicle can notify other vehicles of its position and conditions. In the case of a vehicle connected and automated, V2X information may be used for object information. To crop an object cluster detected from the sensor data (image 500), convex hull coordinates of the detected object cluster may be used. For clarity, FIGS. 11 and 12 illustrate detected and cropped object clusters in the low-risk area and the high-risk area, respectively. However, the decision-making unit filters each area based on accuracy of a position and conditions of the vehicle. Thus, the block 313 (bandwidth-based compression unit) may receive detected and cropped object clusters in either the high-risk area or the low-risk area, or all the object clusters may be supplied to the block 316.

FIG. 13 illustrates an environmental scene reproduced on a remote assistance side using the detected, cropped, and compressed object cluster, and the map data illustrated in FIG. 7. Thus, when the accuracy of a position and conditions of the vehicle is less than an acceptable limit, the vehicle may transmit both of the object cluster detected, cropped, and compressed in the low-risk area, and the object cluster detected, cropped, and compressed in the high-risk area. In such a situation, the object cluster detected, cropped and compressed in the low-risk area can be used for feature matching and output of positional information with high accuracy, while at the same time the object cluster detected, cropped and compressed in the high-risk area can be used for making a secure driving decision.

### Second Embodiment

A second embodiment is achieved by adding a more specific description and adding or changing some configurations and operations in the first embodiment.

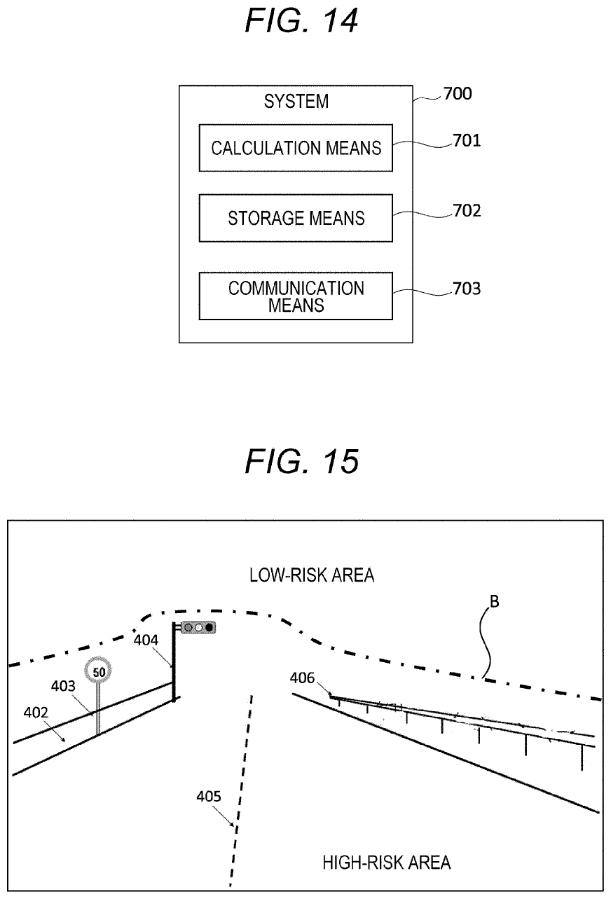

FIG. 14 illustrates an example of a configuration of a system 700 according to the second embodiment. The system 700 makes a decision based on data communication. The system 700 has a configuration known as s computer, and includes a calculation means 701, storage means 702, and communication means 703.

The calculation means 701 includes, for example, a processor. The storage means 702 includes a storage medium such as a semiconductor memory or a magnetic disk device. The communication means 703 includes input-output means such as an input-output port or a communication antenna. The communication means 703 can perform wireless communication through, for example, a wireless communication network. The system 700 can communicate with an external computer (e.g., a remote assistance system or a decision-making system mounted on another vehicle) using the communication means 703. The system 700 may include input-output means other than the communication means 703.

The system 700 has functions of performing the respective processes illustrated in FIG. 3. For example, the storage means 702 stores programs for executing the respective processes illustrated in FIG. 3, and the calculation means 701 executes the programs to implement respective functions illustrated in FIG. 3.

The system 700 can be mounted on, for example, a vehicle (the vehicle 200 illustrated in FIG. 2 as a specific example). In that case, the system 700 may determine operation of the vehicle. Examples of contents of decision-making include a level of vehicle speed, a level of accelerator opening, whether to brake, whether to stop, whether to change a lane, whether to steer to the left, whether to steer to the right, and what is a steering angle to the left or right.

The system 700 may be mounted in a configuration other than a vehicle. The system 700 may be mounted on a vehicle other than that illustrated in FIG. 2, such as a passenger car, a bus, a truck, a train, or a golf cart, an industrial machine such as a construction machine or a farm machine, a robot such as a ground robot, a water robot, a warehouse robot, or a service robot, an aircraft such as a fixed-wing aircraft or a rotary-wing aircraft, or a ship such as a boat or a ship, for example, and may make a decision related to operation thereof or determination of a situation. The system 700 may be configured to be movable by being mounted on a movable structure (a vehicle, etc.), or may be configured to be immovable by being mounted on a fixed structure.

Hereinafter, the vehicle 200 illustrated in FIG. 2 will be described as an example. The vehicle 200 is, for example, a passenger car. The system 700 is connected to one or more sensors for acquiring information about surrounding environment. These sensors are mounted on, for example, the vehicle 200. The surrounding environment represents a situation of objects around the system 700. The objects around the system 700 are detected as objects around the vehicle 200 in the present embodiment, but are not necessarily detected as objects related to the vehicle 200.

The sensors include a distance sensor that measures a distance to an object around the vehicle 200. The distance sensor may include a RADAR sensor. The example of FIG. 2 includes the front RADAR sensor 201 and the rear RADAR sensor 209. The distance sensor may also include an ultrasonic sensor. The example of FIG. 2 includes the front ultrasonic sensor 202 and the rear ultrasonic sensor 210. The distance sensor may also include the LIDAR sensor 206.

The sensors may also include an image sensor (imaging means) that captures an image of surroundings of the vehicle 200. The example of FIG. 2 includes the first front camera 203, the side camera 204, the rear camera 208, and the second front camera 205, as image sensors.

The sensors may also include a position sensor that acquires position information on the vehicle. The example of FIG. 2 includes the GPS and the INS 207 as position sensors.

The system 700 performs the processes illustrated in FIG. 3. The processes are started, for example, periodically or based on a predetermined execution start signal received from the outside.

In step 301 of FIG. 3, the system 700 may receive data from each of the sensors described above. These data may be configured to allow determination or estimation of, for example, a position of each of objects around the vehicle 200 with respect to the vehicle 200 (or with respect to the corresponding one of the sensors), a distance from the vehicle 200 (or from each sensor) to the corresponding one of the objects, a type of each of the objects, and a behavior (e.g., a movement direction and speed of an object) of each of the objects.

In step 302 of FIG. 3, the system 700 may acquire a map image. The map image means, for example, an image illustrating a geographical situation of surrounding environment. The map image is acquired as, for example, an image as illustrated in FIG. 8. Although FIG. 8 is not a diagram directly illustrating the map image, the map image obtained as a result may be an image as illustrated in FIG. 8.

In the example of FIG. 8, the map image includes images representing the road structural features 402 to 406. The road structural feature 402 represents a sidewalk, the road structural feature 403 represents a traffic sign, the road structural feature 404 represents a traffic light, the road structural feature 405 represents a lane boundary, and the road structural feature 406 represents a guardrail.

The map image may be received from an external computer through a communication network, or may be stored in advance in the storage means 702 of the system 700. The map image may be also directly acquired as an image, or may be acquired as an image format after information acquired in a format other than an image is converted. The conversion may be executed with reference to other information. For example, the system 700 may acquire map information in a two-dimensional format and generate a pseudo-three-dimensional map image as illustrated in FIG. 8 based on a position of the vehicle 200 on the map. This map information includes information representing the road structural features 402 to 406 illustrated in FIG. 8.

In step 303 of FIG. 3, the system 700 may determine first and second areas in the map image. Three or more areas may be determined. The first area and the second area may be determined as areas that do not overlap each other, or may be allowed to overlap each other. These areas are determined, for example, based on a fixed or adaptively determined boundary. Although a specific method for determining these areas can be appropriately designed by those skilled in the art, the method described in PTL 1 can be used, for example. The contents of PTL 1 are incorporated herein by reference.

FIG. 15 illustrates an example of these areas. The map image illustrated in FIG. 8 includes an area below a boundary line B in the paper surface (i.e., a side including a road surface in the image), serving as the first area, and an area above the boundary line B in the paper surface (i.e., a side including a sky area in the image), serving as the second area.

The first area is likely to include an object directly related to safety for the moving vehicle 200, and can be called a high-risk area. The first area is also likely to include an object moving with respect to the road surface, and can also be called a dynamic area. In contrast, the second area is unlikely to include an object directly related to safety for the moving vehicle 200, and can be called a low-risk area. The second area is also unlikely to include an object moving with respect to the road surface, and can also be called a static area.

Hereinafter, although in the present embodiment, the first area is referred to as the “high-risk area” and the second area is referred to as the “low-risk area”, for convenience of explanation, names of these areas are not essential to the present invention.

In step 304 of FIG. 3, the system 700 determines whether to transmit data related to the high-risk area through the communication network (a first transmission determination function). The data is, for example, image data related to each object, and may include data other than the image data. This determination can be executed based on any criteria, and an example of the determination is described below.

The first transmission determination function may be executed, for example, based on an effective communication rate of the communication network. More specifically, when the effective communication rate of the communication network to the remote support system is equal to or higher than a predetermined threshold value, it is determined that data related to the high-risk area should be transmitted, and otherwise it is determined that the data should not be transmitted. According to such criteria, the amount of data to be communicated can be reduced. In particular, when the effective communication rate is low, communication capacity can be saved for other more important data.

The effective communication rate may be a value called “bandwidth”, “channel capacity”, “transmission line capacity”, “transmission delay”, “network capacity”, “network load”, or the like. A method for measuring the effective communication rate can be appropriately designed by those skilled in the art based on known techniques and the like.

The first transmission determination function may be executed based on the number of objects detected in the high-risk area, which is, for example, determined in step 306 or 307. In that case, the first determination function may be executed after step 307, but before step 309. More specifically, when the number of objects exceeding a predetermined threshold value belongs to the high-risk area, it is determined that the data related to the high-risk area should be transmitted, and otherwise it is determined that the data should not be transmitted. According to such criteria, when the number of objects exceeding a limit that can be processed by the system 700 itself is detected, assistance of the remote assistance system can be appropriately requested.

The first transmission determination function may be executed based on a comparison of computational capability between the system 700 and the remote assistance system. For example, the function may be executed based on a relative value representing the computational capability of the system 700 with respect to the remote assistance system. Such a relative value can be determined using a function, which may be, for example, a simple division or subtraction, the function including a value representing the computational capability of the remote assistance system and a value representing the computational capability of the system 700. For example, when the system 700 has a failure, the computational capability of the system 700 may be evaluated lower.

As a more specific example, when a relative value representing the computational capability of the system 700 is equal to or more than a predetermined threshold value, it is determined that the data related to the high-risk area should not be transmitted, and otherwise it is determined that the data should be transmitted. According to such criteria, the amount of data to be communicated can be reduced. Only when determination capability of the system 700 itself is insufficient, the assistance of the remote assistance system can be efficiently requested.

The first transmission determination function may be executed by combining the plurality of criteria described above.

In step 304 of FIG. 3, the system 700 determines whether to transmit data related to the low-risk area through the communication network (a second transmission determination function). The data is, for example, image data related to each object, and may include data other than the image data. This determination can be executed based on any criteria, and an example of the determination is described below.

The second transmission determination function may be executed, for example, based on accuracy of a position of the system 700. In the present embodiment, the position of the system 700 can be regarded as the same as the position of the vehicle 200. For example, the system 700 can acquire or calculate the position of the system 700 and accuracy of the position (i.e., the position of the vehicle 200 and accuracy of the position) based on data detected by the GPS and the INS 207. When the accuracy is equal to or more than a predetermined threshold value, it is determined that data related to the low-risk area should not be transmitted, and otherwise it is determined that the data should be transmitted.

Here, the low-risk area is likely to include many static features related to the map image, and thus is likely to be useful for precise determination of the position of the vehicle 200 or the system 700. Thus, according to such criteria, assistance of the remote assistance system can be appropriately requested only when it is difficult for the system 700 to identify its own position independently.

In the present embodiment, the system 700 may not necessarily operate in step 304 according to FIG. 5. In particular, the first transmission determination function and the second transmission determination function can be executed based on various conditions as follows.

The conditions referred to in the first transmission determination function and the second transmission determination function may include an effective communication rate of the communication network, the number of detected objects, a computational capability value of the remote assistance system, a computational capability value of the system 700, accuracy of a position of the system 700, and moving speed of the system 700 (i.e., traveling speed of the vehicle 200), for example. Additionally, various combination patterns of these conditions may be defined, and the storage means 702 may store a determination table in which whether data related to the high-risk area should be transmitted is associated with whether data related to the low-risk area should be transmitted, for each of the patterns. On the basis of these conditions, the system 700 can perform the first transmission determination function and the second transmission determination function with reference to the determination table.

In step 305 or step 306 of FIG. 3, the system 700 may detect objects around the vehicle 200. For example, objects in the surrounding environment are detected individually or as a cluster including a plurality of objects. The processes of steps 305 and 306 may be executed based on the data received in step 301.

In the example of FIG. 13, a plurality of vehicles is detected in a state clustered in one cluster. In the description of the present embodiment, the case where objects are detected individually and the case where objects are detected as a cluster including a plurality of objects are not distinguished below.

As a more specific example, when the first front camera 203 detects an image as illustrated in FIG. 1, a surrounding object may be detected by detecting an object appearing in the image. When a field of view of an image detected by a camera or the like does not match a field of view of a map image, conversion may be executed to match one field of view with the other field of view. Alternatively, when a map image is acquired or generated, a field of view of the map image may be matched to that of an image detected by a camera or the like.

Surrounding objects may be detected based on other data. For example, the objects may be detected based on an image detected by another camera, or may be detected based on data detected by a sensor other than the camera, such as a LIDAR sensor, a RADAR sensor, an ultrasonic sensor, or an audio sensor.

In step 306 or 307 of FIG. 3, the system 700 may determine positions of the respective detected objects in the map image. The positions are represented by, for example, a two-dimensional coordinate system, and can be represented as a set consisting of coordinates of respective vertexes of a convex hull. This process may be implemented as so-called cropping. Specific contents of the process can be appropriately designed by those skilled in the art based on a public known art and the like.

In step 306 or 307 of FIG. 3, for each of the objects, the system 700 may determine whether the object belongs to the high-risk area based on its position in the map image. Similarly, for each of the objects, the system 700 may determine whether the object belongs to the low-risk area based on its position in the map image. The determination of each area does not need to be executed independently, and for example, an object determined not to belong to the high-risk area may inevitably be treated as belonging to the low-risk area.

In this determination, when a part of an object belongs to one area and another part of the object does not belong to the one area (e.g., when the object exists across high-risk and low-risk areas), processing of the determination can be appropriately designed by those skilled in the art. For example, the object may be determined based on its center of gravity on an image.

In step 308 of FIG. 3, for each of the objects, the system 700 may determine a data compression ratio for the object based on a distance to the object (compression ratio determination function). When the data compression ratio is appropriately determined, the amount of data to be communicated can be reduced.

For example, an object with a short distance may be determined to have a small data compression ratio (i.e., a large amount of data after compression or a small amount of information loss), and an object with a large distance may be determined to have a large data compression ratio (i.e., a small amount of data after compression or a large amount of information loss). In the present embodiment, the system 700 may not necessarily operate in step 308 according to FIG. 6.

This causes an object that is more important in determining operation of the system 700 or vehicle 200, i.e., an object that is closer to the system 700 or vehicle 200, to have a small amount of loss by using a larger amount of data. As a result, more secure operation of the vehicle 200 is likely to be able to be determined. In contrast, for an object that is less important in determining the operation of the system 700 or vehicle 200, i.e., an object that is farther from the system 700 or vehicle 200, data is compressed more strongly to reduce the amount of the data, so that communication capacity can be saved.

The compression ratio determination function does not need to be executed based only on a distance to an object, and other criteria may be used in combination. For example, the function may be executed based further on a type (class) of each object or a behavior of each object. As a more specific example, a compression ratio may be reduced when the object is a pedestrian, and may be increased when the object is a vehicle. In particular, for a vehicle, the amount of data after compression may be zero or almost zero, or image information may be discarded to leave only convex hull information. This enables assistance of the remote assistance system to be appropriately requested by reducing the amount of information on a vehicle that frequently appears in an image of an in-vehicle camera, and leaving more information on a pedestrian that appears less frequently.

Alternatively, when an object is approaching the vehicle 200 (or system 700), a compression ratio may be reduced, and when an object is moving away from the vehicle 200 (or system 700), a compression ratio may be increased. This enables assistance of the remote assistance system to be appropriately requested by leaving more information on an object that is important for determining operation of the vehicle 200.

Alternatively, the compression ratio determination function may be further executed based on an effective communication rate of the communication network. As a more specific example, when the effective communication rate is equal to or higher than a predetermined threshold value, the compression ratio may be reduced, and otherwise the compression ratio may be increased. This enables communication with an appropriate amount of data to be achieved according to available communication capacity.

For an area determined not to transmit data, execution of the compression ratio determination function may be eliminated. For example, when it is determined not to transmit data related to the high-risk area, a data compression ratio of an object belonging to the high-risk area does not need to be determined.

In step 309 of FIG. 3, the system 700 may compress data related to each of the objects according to the data compression ratio of the object, so that compressed data related to the object may be generated. Here, the data to be compressed is, for example, image data related to the object, and may include data other than the image data.

This process may be eliminated for the area determined not to transmit data. For example, when it is determined not to transmit data related to the high-risk area, compression data related to an object belonging to the high-risk area does not need to be generated.

In step 309 of FIG. 3, the system 700 may transmit compressed data to be transmitted. That is, when it is determined that the data related to the high-risk area should be transmitted, the compressed data related to each object belonging to the high-risk area is transmitted through the communication network. When it is determined that the data related to the low-risk area should be transmitted, the compressed data related to each object belonging to the low-risk area is transmitted through the communication network. Here, the data determined not to be transmitted is not transmitted, so that the amount of data to be communicated can be reduced.

These compressed data are transmitted to, for example, the remote assistance system. As a modification, these compressed data may be transmitted to a computer system other than the remote assistance system. For example, the data may be transmitted to another system being mounted on a vehicle other than the vehicle 200 and having the same configuration as the system 700. In that case, the other system may function as a relay base between the system 700 and the remote assistance system. Additionally, in that case, the other system may function as a relay base between a plurality of systems including the system 700 and the remote assistance system. This enables reducing the number of systems that directly communicate with the remote assistance system, and reducing congestion of communication in the remote assistance system.

Although not illustrated in FIG. 3, the remote assistance system or another computer system receives the transmitted compressed data and transmits reply data accordingly. This reply data may be relayed by the other computer system, such as the compressed data described above.

In step 310 of FIG. 3, the system 700 may receive the data (reply data) replied through the communication network. This reply data is replied in association with the compressed data transmitted by the system 700. A method for generating the reply data can be appropriately designed. For example, the reply data may be generated to make a decision on the vehicle 200 based on the compressed data acquired by the remote assistance system. Alternatively, a human operator may browse the compressed data and the reply data may be input accordingly. Alternatively, the remote assistance system may execute machine learning based on the compressed data, and the reply data may be generated using a trained model generated by the machine learning.

In step 310 of FIG. 3, the system 700 may make a decision in accordance with the reply data. For example, when the reply data includes an instruction to brake, the system 700 may make a decision to brake. When the reply data includes information indicating road conditions, the system 700 may determine operation of the vehicle 200 based on the road conditions.

### REFERENCE SIGNS LIST

200 vehicle
201 front RADAR sensor
202 front ultrasonic sensor
203 first front camera
204 side camera
205 second front camera
206 LIDAR
207 INS
208 rear camera
209 rear RADAR sensor
210 rear ultrasonic sensor
401 landmark feature
402-406 road structural features
500 driving environment image
501 traffic light
502 static feature
503,505 pedestrian
504 road sign
506 traffic participant
507 sidewalk lane
510 lane information
513 guardrail
700 system (system making a decision based on data communication)
701 calculation means
702 storage means
703 communication means
   All publications, patents, and patent applications cited herein are incorporated herein by reference in their entirety.

1. A system that makes a decision based on data communication, the system comprising:
a function of acquiring a map image;
a function of determining a first area and a second area in the map image;
a first transmission determination function of determining whether to transmit data related to the first area through a communication network;
a second transmission determination function of determining whether to transmit data related to the second area through the communication network;
a function of detecting objects around the system;
a function of determining a position in the map image for each of the objects detected;
a function of determining whether each of the objects detected belongs to the first area, based on the position of the corresponding one of the objects in the map image;
a function of determining whether each of the objects detected belongs to the second area, based on the position of the corresponding one of the objects in the map image;
a compression ratio determination function of determining a data compression ratio for each of the objects detected, based on a distance to the corresponding one of the objects;
a function of compressing data related to each of the objects detected in accordance with the data compression ratio of the corresponding one of the objects to generate compression data related to the corresponding one of the objects;
a function of transmitting the compression data related to each of the objects belonging to the first area through the communication network when data related to the first area is determined to be transmitted;
a function of transmitting the compression data related to each of the objects belonging to the second area through the communication network when data related to the second area is determined to be transmitted;
a function of receiving reply data replied in association with the compression data transmitted, through the communication network; and
a function of making a decision in accordance with the reply data.

2. The system according to claim 1, wherein the system is mounted on a vehicle and determines operation of the vehicle.

3. The system according to claim 1, wherein the first transmission determination function is executed based on an effective communication rate of the communication network.

4. The system according to claim 1, wherein
the system is mobile,
the system has a function of acquiring accuracy of a position of the system, and
the second transmission determination function is executed based on the accuracy.

5. The system according to claim 1, wherein the compression ratio determination function is further executed based on a type of each of the objects or a behavior of each of the objects.

6. The system according to claim 1, wherein the compression ratio determination function is further executed based on an effective communication rate of the communication network.
